(19) United States
(12) Patent Application Publication
(10) Pub. No.: US 2011/0126897 A1
(43) Pub. Date: Jun. 2, 2011

(54) COMPOSITION FOR EXTRUDING FIBERS

(75) Inventors: FENG GAO, HOCKESSIN, DE (US); PAUL DOUGLAS VERNOOY, HOCKESSIN, DE (US)

(73) Assignee: E. I. DU PONT DE NEMOURS AND COMPANY, Wilmington, DE (US)

(21) Appl. No.: 12/782,793

(22) Filed: May 19, 2010

Related U.S. Application Data
(60) Provisional application No. 61/179,733, filed on May 20, 2009.

(51) Int. Cl. H01L 31/0224; C09K 13/00; C04B 35/622

(52) U.S. Cl. 136/256; 252/79.1; 427/74

(57) ABSTRACT

The present invention relates a composition which is useful in printing by extruding a metalized fiber on a substrate. Zinc oxide is incorporated in combination with glass frit into a composition to etch the substrate and a binder polymer is used to allow extrusion of narrow fibers which also may have adequate height to provide sufficient electrical conduction. The present invention is also a process to extrude a pattern of the composition. The present invention is further directed to a solar cell formed from such composition and the process.

### FIELD OF THE INVENTION

The present invention relates a composition which is useful in extruding a fiber of the composition on the front surface of solar cells. Zinc oxide is incorporated in combination with glass frit to etch a front surface antireflective coating and a binder polymer is used to allow extrusion of narrow lines which also may have adequate height to provide sufficient electrical conduction. The present invention is also a process to extrude a pattern of the composition of the present invention. The present invention further directs to a solar cell formed from such composition and the process.

### TECHNICAL BACKGROUND

Carroll et al. (U.S. Pat. No. 7,435,361) describe a thick film paste using a binder which comprises ethyl cellulose, ethylhydroxyethyl cellulose, wood rosin, mixtures of ethyl cellulose and phenolic resins, polymethacrylates of lower alcohols, or monobutyl ether of ethylene glycol monoacetate.

U.S. Pat. No. 5,174,925 describes a thick film paste using a binder which comprises poly(isobutyl methacrylate), poly(isopropyl methacrylate), poly(methyl methacrylate), poly(4-fluorethylene), poly(alpha-methyl styrene), copolymer of alpha-methyl styrene and isobutyl methacrylate, copolymer of alpha-methyl styrene, isobutyl methacrylatre and methyl methacrylate, copolymer of alpha-methyl styrene and isopropyl methacrylate, copolymer of alpha-methyl styrene, isopropyl methacrylate, and methyl methacrylate.

There is a need for a composition to be used to print electrical conductors on the front surface of photovoltaic cells with antireflective coatings. The advantage of this invention is to use the method of extrusion to make fibers producing high aspect ratio (height to width) grid lines with a height greater than 12 microns and width less than 120 microns (values are after firing process).

### BRIEF DESCRIPTION OF THE DRAWINGS

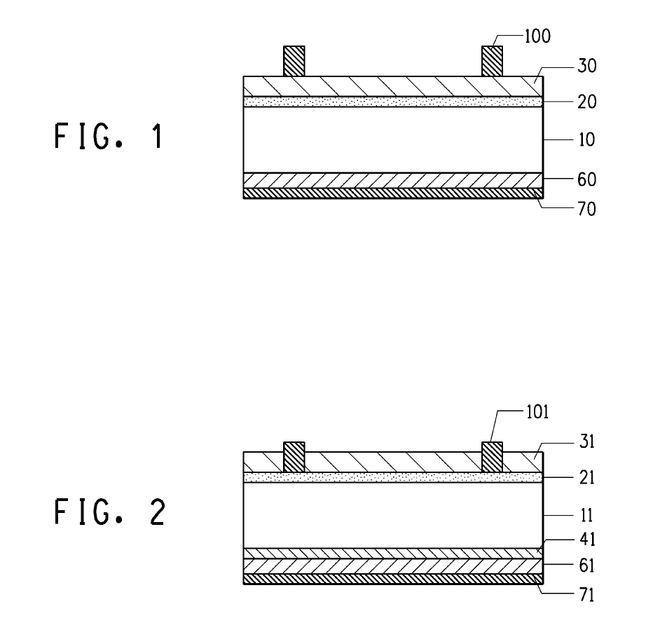

FIG. 1 shows a cross section diagram of an exemplary wafer solar cell (p-type wafer) before a firing process.
10: p-type silicon substrate
20: n-type diffusion layer
30: silicon nitride film, titanium oxide film, or silicon oxide film
60: aluminum paste formed on backside
70: silver or silver/aluminum paste formed on backside
100: silver paste formed on front side

FIG. 2 is a cross section diagram of an exemplary wafer solar cell (p-type wafer) after the firing process.
11: p-type silicon substrate
21: n-type diffusion layer
31: silicon nitride film, titanium oxide film, or silicon oxide film
41: p+ layer (back surface field, or BSF)
61: aluminum back electrode (obtained by firing backside aluminum paste)
71: silver or silver/aluminum back electrode (obtained by firing back side silver paste)
101: silver front electrode (formed by firing front side silver paste)

### SUMMARY OF THE INVENTION

The present invention is a composition comprising, based on total composition:
a) 30 to 98% by weight of metal powder;
b) 0.1 to 15% by weight of glass frit;
c) 0.1 to 8% by weight of ZnO;
d) 1 to 10% by weight of a binder selected from the group consisting of cellulose derivatives (methyl cellulose, hydroxypropyl methyl cellulose, hydroxyethyl methyl cellulose, hydroxyethyl ethyl cellulose, hydroxyethyl cellulose, 2-hydroxyethyl cellulose, and hydroxypropyl cellulose), cellulose ethers, cellulose acetates, tragacanth gum, gum arabic, cyamoposis gum, gum dammer, locust bean gum, xantham gum, lignosulfonates, casein, alginates, acylglycerides, polyvinylpyrrolidone, poly(vinyl pyrrolidone-vinyl acetate)s, poly(2-ethyl-2-oxazoline), polyvinyl alcohols, poly(acrylic acid)s, copolymers of acrylic acid that are soluble in water, poly(ethylene oxide)s, poly(propylene oxide)s, copolymers of ethylene oxide and propylene oxide, and latex emulsions selected from acrylic, acrylic-styrene, vinyl-acrylic, or urethane-acrylic; and
e) 10 to 50% water.

The invention is also directed to a composition comprising, based on total composition:
a) 30 to 98% by weight of metal powder;
b) 0.1 to 15% by weight of glass frit;
c) 0.1 to 8% by weight of ZnO;
d) 1 to 10% by weight of a binder selected from the group consisting of poly(vinyl acetate)s, poly(vinyl acetate-carbon monoxide-ethylene)s, poly(n-butyl acrylate-glycidyl methacrylate)s, poly(ethylene-vinyl acetate)s, poly(vinyl butyral-vinyl alcohol-vinyl acetate)s, poly(vinylidene fluoride), poly(ethylene-tetrafluoroethylene)s, copolymers of vinylidene difluoride, fluoropolymers, poly(acrylonitrile)s, poly(oxymethylene), poly(ethylene terephthalate), poly(ethylene methacrylic acid)s, poly(ethylene acrylic acid)s, poly(ethylene vinyl alcohol)s, poly(organosiloxane)s, polyurethanes, polyethers, polyesters, polycarbonates, polyamides, epoxy resins, and phenolic resins; and
e) 10 to 50% an organic solvent.

The present invention is further a process comprising:
a) extruding into a fiber the above compositions
b) depositing the fiber on a substrate;
c) removing the solvent; and
d) firing the substrate.

The present invention is further directed to a solar cell or module using the composition and the process described above.

### DETAILED DESCRIPTION

Conventional conductive pastes used in electronic materials are viscous liquids at room temperature. Such pastes typically consist of conductive powders or flakes and adequate additives dispersed in a liquid vehicle. Such pastes are applied to substrates by conventional methods such as screen printing, pad printing, and other application methods, which are well known. Screen printing is widely adopted for printing thick pastes on crystalline wafers for photovoltaic cells as the most common print method.

One of the problems associated with the use of screen printing on photovoltaic cells is that it creates conductor grid lines with low aspect ratios (height to width), around 0.1. The wide grid lines block sunlight into the cells so that the cell efficiency is reduced. In addition, it is a contact printing method, which leads to breakage of the wafer cells. Therefore, it is highly desirable to develop a printing method that is non-contact and can print narrow grid lines with high aspect ratio.

Provided herein is a composition and a method that can produce conductor grid lines having a high aspect ratio on wafers. The silver conductor lines located on the front surface of solar cells may be extruded as fibers of thick film pastes comprising binders. Pastes with zinc oxide are particularly useful for extruding conductor fibers on the front (sun exposed) side of solar cells with antireflective coatings.

Fork et al. in US2008/0102558 disclose a method to obtain high aspect ratio gridlines by extrusion. However, in their method, extra extrusion heads have to be used to co-extrude the desired conductor grid lines along with the sacrificial materials, which increase the costs of the extruder and the consumption of materials. In the present invention, the grid lines can be extruded directly with a solvent-based paste without using sacrificial barriers or walls to support the silver line. It is simple and inexpensive, which consequently reduces the printer investment and manufacturing cost of photovoltaic cells and modules. In addition, water is used (as the most preferred solvent) to further lower cost and to ease environmental concerns.

Extrusion is a well known technology to make thin fibers. It is also a versatile method to get fibers with various shapes of the cross section of the fibers using different extrusion dies. During extrusion a billet of materials is pushed and/or drawn through a die to create a rod, rail, pipe, etc. Various applications leverage this capability. For example, extrusion can be used with food processing applications to: create pasta, cereal, snacks, etc.; pipe pastry filling; pattern cookie dough on a cookie pan; and generate pastry flowers and borders on cakes. Depending on the requirements of the application, various extruders are available, for instance, single screw extruders, twin screw extruders, etc. Extensive information on extrusion technology can be found in the following references and therefore detailed description of extrusion is not discussed herein. References on extrusion include: Extrusion: The Definitive Processing Guide and Handbook; Harold, F. Giles, Jr., John R. Wagner, Jr.; William Andrew Publishing, Burlington, Mass., 2005; and Plastic Extrusion Technology Handbook, 2^{nd} Edition; Sidney J. Levy, James, F. Carley and James, M. McKelvey; Industrial Press, Inc., New York, N.Y., 1989.

### Electrically Conductive Metal Powders

Generally, a conductive ink composition comprises conductive particles for conduction of electrons. Silver particles are preferred although other metals such as Cu, Ni, Al, Pd, or mixtures or alloys of these with Ag may be used. The particles can be spherical, platelets or flakes in shape. The silver particles may be coated or uncoated. When the silver particles are coated, they are at least partially coated with a surfactant. The surfactant may be selected from, but is not limited to, stearic acid, palmitic acid, a salt of stearic acid, a salt of palmitic acid, and mixtures thereof. Other surfactants may be utilized including lauric acid, oleic acid, capric acid, myristic acid, and linolic acid. The counter-ion can be, but is not limited to, hydrogen, ammonium, sodium, potassium, and mixtures thereof.

The particle size of the silver is not subject to any particular limitation, although an average particle size of about 10 micrometers to 5 micrometers is desirable. Typically, particles less than 5 nm are very expensive, and thus they are not usually considered for commercial use. The composition comprises, based on total composition 30 to 98% by weight of metal powders. More preferably, the metal content is between 70% and 90%.

### Inorganic Additives

ZnO (zinc oxide) is added as a functional component in combination with glass frit to etch through the front side antireflective coating layer (e.g., silicon nitride) and to form good contact with low contact resistance. The silicon nitride layer may be formed, for example, by thermal chemical vapor deposition (CVD), plasma-enhanced chemical vapor deposition (PECVD), or a sputtering process. Although ZnO is more preferred, other Zn-containing additives may be used. The additive may be Zn, an oxide of Zn, compounds that can generate an oxide of Zn upon firing, and mixtures thereof. Preferably, the additive particle size is less than 10 micrometers, more preferably it is less than 5 micrometers, and most preferably it is less than 2 micrometers. Particles less than 5 nm are typically too expensive to be considered for commercial uses. The composition comprises, based on total composition 0.1 to 8% by weight of the additive, and preferably comprises 1 to 7% ZnO.

### Glass Frit

Examples of the glass frits which may be used in the present invention include amorphous, partially crystallizable lead silicate glass compositions as well as other compatible glass frit compositions. In a further embodiment these glass frits are cadmium-free. Additionally, in a further embodiment, the glass frit composition is a lead-free composition. An average particle size of the glass frit of the present invention is in the range of 0.5 to 1.5 microns in practical applications, while an average particle size in the range of 0.8 to 1.2 microns is preferred. The softening point of the glass frit (T_{c}, the second transition point in the DTA) should be in the range of 300 to 600° C.

The glasses described herein are produced by conventional glass making techniques known to those skilled in the art. More particularly, the glasses may be prepared as follows: Glasses are typically prepared in 500 to 1000 gram quantities. The ingredients are weighed, mixed in the desired proportions, and heated in a bottom-loading furnace to form a melt in a platinum alloy crucible. Heating is typically conducted to a peak temperature (1000 to 1400° C.) and for a time such that the melt becomes entirely liquid and homogeneous. The glass melts are then quenched by pouring them out onto the surface of counter-rotating stainless steel rollers to form a 10 to 20 mil thick platelet of glass or by pouring into a water tank. The resulting glass platelet or water-quenched frit is milled to form a powder with its 50% volume distribution (d50) between 1 and 5 microns. An average particle size of the glass frit of the present invention is preferred less than 3 micrometers, mostly preferred less than 1.5 micrometer. The composition comprises, based on total composition 0.1 to 15% by weight of the glass frit, preferably 1 to 8% of the glass frit.

### Binders

Binders with desirable solubility in water or an organic solvent can be used in an aqueous system or a solvent based system for this invention. The binder is, when water is used as the solvent includes, but not limited to, cellulose derivatives (methyl cellulose, hydroxypropyl methyl cellulose, hydroxyethyl methyl cellulose, ethyl cellulose, hydroxyethyl ethyl cellulose, hydroxyethyl cellulose, 2-hydroxyethyl cellulose, and hydroxypropyl cellulose), cellulose ethers, cellulose acetates, tragacanth gum, gum arabic, cyamoposis gum, gum dammer, locust bean gum, xantham gum, lignosulfonates, casein, alginates, acylglycerides, polyvinylpyrrolidone, poly(vinyl pyrrolidone-vinyl acetate)s, poly(2-ethyl-2-oxazoline), polyvinyl alcohols, poly(acrylic acid)s, copolymers of acrylic acid that are soluble in water, poly(ethylene oxide)s, poly(propylene oxide)s, copolymers of ethylene oxide and propylene oxide, orlatex emulsions (acrylic, acrylic-styrene, vinyl-acrylic, and urethane-acrylic). The binder is in the range, based on total composition 1 to 10% by weight. A water soluble binder is preferred throughout the application because of environmental considerations.

In another embodiment of the invention, the binder is, for non-aqueous, organic solvents may include, but is not limited to, poly(vinyl acetate)s, poly(vinyl acetate-carbon monoxide-ethylene)s, poly(n-butyl acrylate-glycidyl methacrylate)s, poly(ethylene-vinyl acetate)s, poly(vinyl butyral-vinyl alcohol-vinyl acetate)s, poly(vinylidene fluoride), poly(ethylene-tetrafluoroethylene)s, copolymers of vinylidene difluoride, fluoropolymers, poly(acrylonitrile)s, poly(oxymethylene), poly(ethylene terephthalate), poly(ethylene methacrylic acid)s, poly(ethylene acrylic acid)s, poly(ethylene vinyl alcohol)s, poly(organosiloxane)s, polyurethanes, polyethers, polyesters, polycarbonates, polyamides, epoxy resins, and phenolic resins. The binder is in the range, based on total composition 1 to 10% by weight.

### Solvents

Water is the preferred solvent. Organic solvents may be used when an organic solvent based binder is used. Preferably, the solvents have boiling points in the range 80 to 300° C. Solvents with boiling point too low evaporate too quickly, leaving dry paste around the die holes and causing clogging. When the boiling points of the solvents are too high, removing the remaining solvent becomes difficult, raising the cost of drying. The solvent is in the range, based on total composition 1 to 50% by weight.

### Additives

The composition may further contain amounts of, but is not limited to, additives such as thixotrope agents, wetting agents, foaming agents, antifoaming agents, flow agents, plasticizers, lubricants, dispersants, surfactants, and the like to modify one or more properties of the paste or to assist the processes of dispersion, mixing, or extrusion.

### Crystalline Silicon Wafer Solar Cells

The composition as described herein is used to fabricate grid lines on solar cells. The composition is capable of producing grid lines having a high aspect ratio which improves cell efficiency. A conventional solar cell structure with a p-type base has a negative electrode that is typically on the front-side or sun-side of the cell and a positive electrode on the backside. It is well-known that radiation of an appropriate wavelength falling on a p-n junction of a semiconductor body serves as a source of external energy to generate hole-electron pairs in that body. Because of the potential difference which exists at a p-n junction, holes and electrons move across the junction in opposite directions and thereby give rise to flow of an electric current that is capable of delivering power to an external circuit. Most solar cells are in the form of a silicon wafer that has been metalized, i.e., provided with metal contacts that are electrically conductive.

FIG. 1 shows a cross section diagram of an exemplary wafer solar cell (p-type silicon wafer) before a firing process. In FIG. 1, layer 10 is the p-type silicon substrate, which can be either single or multi-crystalline Si. An n-type diffusion layer, 20, of the reverse conductivity type is formed by a thermal diffusion of phosphorus (P) or the like. Phosphorus oxychloride (POCl₃) is commonly used as the phosphorus diffusion source. This diffusion layer has a sheet resistivity on the order of several tens of ohms per square (Ω/□), and a thickness of about 0.3 to 0.5 μm. Next, a silicon nitride film, 30, is formed as an anti-reflection coating on the n-type diffusion layer, 20, to a thickness of about 70 to 90 nm by a process such as thermal CVD, PECVD, or sputtering. A silver paste (e.g., in form of grid lines and bus bars), 100, for the front electrode is printed by such techniques as screen printing or ink jet printing and then dried over the silicon nitride film, 30. In addition, a backside silver or silver/aluminum paste, 70, and an aluminum paste, 60, are then screen printed and successively dried on the backside of the substrate. Firing is then carried out in an infrared furnace at a temperature range of approximately 700 to 975° C. for a period from several seconds to several minutes.

FIG. 2 is a cross section diagram of an exemplary wafer solar cell (p-type) after the firing process. The aluminum diffuses from the aluminum paste into the silicon substrate, 11, as a dopant during firing, forming a p+ layer, 41, containing a high concentration of aluminum dopant. This layer is generally called the back surface field (BSF) layer, and helps to improve the energy conversion efficiency of the solar cell. The aluminum paste is transformed by firing from a dried state in FIG. 1, 60, to an aluminum back electrode, 61. The backside silver or silver/aluminum paste of FIG. 1, 70, is fired at the same time, becoming a silver or silver/aluminum back electrode, 71. During firing, the boundary between the backside aluminum and the backside silver or silver/aluminum assumes an alloy state, and is connected electrically well. The aluminum electrode accounts for most areas of the back electrode, owing in part to the need to form a p+ layer, 41. Because soldering to an aluminum electrode is problematical, a silver back electrode is formed over portions of the backside as an electrode for interconnecting solar cells by means of copper ribbon or the like. In addition, the front electrode-forming silver paste of FIG. 1, 100, sinters and penetrates through the silicon nitride film, 31, during firing, and is thereby able to electrically contact the n-type layer, 21. This type of process is generally called “fire through.” This fired through state is shown in layer 101 of FIG. 2.

A process is disclosed comprising fabricating a fiber of the above described composition on a substrate. The substrate may include, for example, a silicon wafer, a solar cell, or a photovoltaic module. The fabricating of the fiber may be accomplished by forcing the composition through an orifice. In an embodiment, a fiber of the composition may be obtained by extrusion of the composition through an orifice in a spinneret.

A solar cell is disclosed comprising a pattern of conductor grid lines on a light-exposable surface wherein the grid lines have a width of less than 120 microns and a thickness greater than 12 microns (dimensions after firing process). Narrow grid lines of conductor less than 120 microns in width are desirable to maintain a large active area on the front (sun exposed) side of solar cells. Narrow grid lines with heights greater than 12 microns are desirable to produce a line with a cross sectional area large enough to provide electrical conductivity for the solar cell.

### EXAMPLES

23.09 g of a lead alumino-borosilicate frit (23.0% SiO₂, 0.4% Al₂O₃, 58.8% PbO, 7.8% B₂O₃, 6.1% TiO₂, 3.9% CdO, all by weight percent.), 30.77 g ZnO, 615.8 g silver powder, and 33.44 g 2-hydroxyethyl cellulose (average molecular weight of ˜720,000) were blended well. The frit and the ZnO had a median particle size of approximately 1.5 microns. The silver powder was a mixture of flakes and spherical particles from 1 to 10 microns. A 2% solution of polyethylene glycol (average molecular weight of ˜400) in water was prepared. The solution was added to the powder mixture while mixing until a thick dough was formed. During the addition of the solvent, 1.073 g Triton X-100 (Dow Chemical, Midland, Mich.) was added. The dough was further mixed by running it several times through the extruder, an air-powered Bonnot 1 inch (2.54 cm) “BB Gun” single screw laboratory extruder (Uniontown, Ohio), with a die on the front with ¼″ (0.64 cm) holes. Finally, a die with 400 micron circular holes was affixed to the extruder, and fibers were extruded either directly onto solar cells, onto glass slides, or onto a rack for later placement onto the cells. The fibers were strong, flexible, and elastic, which allowed them to be stretched into smaller diameters, if desired.

What is claimed is:

1. A composition comprising, based on total composition:
a) 30 to 98% by weight of metal powder;
b) 0.1 to 15% by weight of glass frit;
c) 0.1 to 8% by weight of ZnO;
d) 1 to 10% by weight of a binder selected from the group consisting of cellulose derivatives (methyl cellulose, hydroxypropyl methyl cellulose, hydroxyethyl methyl cellulose, hydroxyethyl ethyl cellulose, hydroxyethyl cellulose, 2-hydroxyethyl cellulose, and hydroxypropyl cellulose), cellulose ethers, cellulose acetates, tragacanth gum, gum arabic, cyamoposis gum, gum dammer, locust bean gum, xantham gum, lignosulfonates, casein, alginates, acylglycerides, polyvinylpyrrolidone, poly(vinyl pyrrolidone-vinyl acetate)s, poly(2-ethyl-2-oxazoline), polyvinyl alcohols, poly(acrylic acid)s, copolymers of acrylic acid that are soluble in water, poly(ethylene oxide)s, poly(propylene oxide)s, copolymers of ethylene oxide and propylene oxide, and latex emulsions selected from acrylic, acrylic-styrene, vinyl-acrylic, or urethane-acrylic; and
e) 10 to 50% water.

2. A composition comprising, based on total composition:
a) 30 to 98% by weight of metal powder;
b) 0.1 to 15% by weight of glass frit;
c) 0.1 to 8% by weight of ZnO;
d) 1 to 10% by weight of a binder selected from the group consisting of poly(vinyl acetate)s, poly(vinyl acetate-carbon monoxide-ethylene)s, poly(n-butyl acrylate-glycidyl methacrylate)s, poly(ethylene-vinyl acetate)s, poly(vinyl butyral-vinyl alcohol-vinyl acetate)s, poly(vinylidene fluoride), poly(ethylene-tetrafluoroethylene)s, copolymers of vinylidene difluoride, fluoropolymers, poly(acrylonitrile)s, poly(oxymethylene), poly(ethylene terephthalate), poly(ethylene methacrylic acid)s, poly(ethylene acrylic acid)s, poly(ethylene vinyl alcohol)s, poly(organosiloxane)s, polyurethanes, polyethers, polyesters, polycarbonates, polyamides, epoxy resins, and phenolic resins; and
e) 10 to 50% an organic solvent.

3. A process comprising:
a) fabricating the composition of claim 1 into a fiber;
b) depositing the fiber on a substrate;
c) removing the solvent; and
d) firing the substrate.

4. A process comprising:
a) fabricating the composition of claim 2 into a fiber;
b) depositing the fiber on a substrate;
c) removing the solvent; and
d) firing the substrate.

5. The process of claim 3 wherein the substrate is selected from Si wafer, solar cell or photovoltaic module.

6. The process of claim 4 wherein the substrate is selected from Si wafer, solar cell or photovoltaic module.

7. The process of claim 3 wherein the fabricating of fiber is by forcing the composition through an orifice.

8. The process of claim 4 wherein the fabricating of fiber is by forcing the composition through an orifice.

9. The process of claim 7 wherein the orifice shape is selected from square, rectangular or triangular.

10. The process of claim 8 wherein the orifice shape is selected from square, rectangular or triangular.

11. The process of claim 3 wherein the fiber is fabricated by extrusion.

12. The process of claim 4 wherein the fiber is fabricated by extrusion.

13. A solar cell comprising a pattern of fibers of the composition of claim 1 on a light-exposable surface wherein the fibers have a height greater than 12 microns and a width less than 120 microns (after firing process).

14. A solar cell comprising a pattern of fibers of the composition of claim on a light-exposable surface wherein the fibers have a height greater than 12 microns and a width less than 120 microns (after firing process).

15. A solar cell comprising a pattern of fibers made using the process of claim 3 on a light-exposable surface wherein the silver lines have a height greater than 12 microns and a width less than 120 microns (after firing process).

16. A solar cell comprising a pattern of fibers made using the process of claim 4 on a light-exposable surface wherein the silver lines have a height greater than 12 microns and a width less than 120 microns (after firing process).
